(19) United States
(12) Patent Application Publication
(10) Pub. No.: US 2009/0042115 A1
(43) Pub. Date: Feb. 12, 2009

(54) Exposure apparatus, exposure method, and electronic device manufacturing method

(75) Inventors: Hideya Inoue, Yokohama (JP); Naomasa Shiraishi, Saitama-shi (JP)

Correspondence Address: STAAS & HALSEY LLP, SUITE 700, 1201 NEW YORK AVENUE, N.W., WASHINGTON, DC, 20005, US

(73) Assignee: NIKON CORPORATION, Tokyo (JP)

(21) Appl. No.: 12/071,912

(22) Filed: Feb. 27, 2008

Related U.S. Application Data
(60) Provisional application No. 60/907,596, filed on Apr. 10, 2007.

(51) Int. Cl. G03F 9/00; G03B 27/68

(52) U.S. Cl. 430/22; 355/52

(57) ABSTRACT

An exposure apparatus for exposing a bright-dark pattern on a substrate via a projection optical system includes a position detection system which detects a plurality of predetermined positions in a unit exposure field of the substrate. A plurality of reference detection positions fall within a range substantially equal to the unit exposure field. A deformation calculation unit calculates a state of deformation in the unit exposure field based on the detection result of the position detection system. A shape modification unit modifies a shape of the bright-dark pattern to be exposed on the substrate based on the deformation state calculated by the deformation calculation unit.

### CROSS-REFERENCE TO RELATED APPLICATIONS

This application claims the benefit of U.S. Provisional Patent Application No. 60/907,596, filed on Apr. 10, 2007.

### BACKGROUND OF THE INVENTION

An embodiment of the present invention relates to an exposure apparatus, an exposure method, and an electronic device manufacturing method. More particularly, the embodiment of the present invention relates to an exposure apparatus and method used in a lithography process for manufacturing electronic devices such as semiconductor devices, imaging devices, liquid crystal display devices, and thin-film magnetic heads.

A plurality of layers of circuit patterns are formed on a wafer (or a substrate such as a glass plate), which is coated with a photosensitive material, in processes for manufacturing devices such as semiconductor devices. An exposure apparatus is required to align a mask, on which a pattern to be transferred (a transferred pattern) is formed, and the wafer, on which a circuit pattern has been formed. The exposure apparatus includes an alignment unit for such alignment, which may be, for example, an imaging type alignment unit.

The imaging type alignment unit illuminates an alignment mark (wafer mark) formed on the wafer with light emitted from a light source. The alignment unit then forms a magnified image of the wafer mark on an imaging device with an imaging optical system and performs image processing on an obtained imaging signal to detect the position of the wafer mark.

A plurality of unit exposure fields are defined on a single wafer in a manner that the unit exposure fields are arranged in a matrix. A circuit pattern or the like corresponding to a functional element, such as an LSI (large-scale integrated) circuit, is formed in each unit exposure field through a single exposure operation (e.g., a one-shot exposure operation or a scanning exposure operation). More specifically, the exposure apparatus repeatedly performs an exposure operation on a single unit exposure field a number of times while step-moving the wafer relative to a projection optical system. As a result, one or more alignment marks are transferred onto each unit exposure field together with one or more LSI circuit patterns.

A conventional position detection apparatus includes a single position detection mechanism (e.g., an alignment microscope) or an X-position detection mechanism and a Y-position detection mechanism that are separately arranged.

A wafer on which a pattern has been exposed and undergone wafer processing, which includes etching and film formation, may be deformed in an in-plane direction. More specifically, the wafer may expand or contract in size entirely or locally from its original shape due to the wafer processing or the like.

In conventional art, to cope with such deformation of a wafer that has undergone exposure and wafer processing, enhanced global alignment (EGA) has been proposed to correct in-plane deformation of a wafer related with the arrangement of unit exposure fields. To cope with linear deformation of each unit exposure field, or more specifically, expansion, contraction, and rotation of each unit exposure field, which is expressed by a linear function using orthogonal coordinates representing an in-plane position of each unit exposure field or X and Y coordinates, a magnification correction method for correcting the magnification of the projection optical system and a mask rotation method for rotating the mask have been proposed.

### BRIEF SUMMARY OF THE INVENTION

In recent years, LSI circuit patterns have been further miniaturized. As a result, patterns are required to be superimposed over one another on the substrate with higher accuracy. Accordingly, in the future, an exposure apparatus will have to correct high-level deformation occurring in the unit exposure fields, whereas such deformations were not taken into consideration in conventional art. A “high-level deformation” refers to higher-order deformation that cannot be expressed by a linear function using X and Y coordinates, or more specifically, deformation expressed by a higher-order function using X and Y coordinates, such as a quadratic function or a cubic function.

To measure such high-level deformation in a unit exposure field, for example, the positions of many discretely formed marks in a unit exposure field must be detected. A conventional position detection apparatus, which includes the single position detection mechanism or the two position detection mechanisms, sequentially detects the positions of the marks and thus takes much time for the detection of every mark position. This lowers the throughput (processing capacity) of the exposure apparatus and makes it difficult to maintain sufficiently high productivity.

It is an object of the embodiment according to the present invention to provide an exposure apparatus and an exposure method enabling rapid and accurate measurement of deformation occurring in a unit exposure field and enabling the superimposition of patterns on a substrate with high accuracy.

A first aspect of the present invention provides an exposure apparatus that exposes a bright-dark pattern on a substrate via a projection optical system. The exposure apparatus includes a position detection system which detects a plurality of predetermined positions in a unit exposure field of the substrate, wherein a plurality of reference detection positions fall within a range substantially equal to the unit exposure field. A deformation calculation unit calculates a state of deformation in the unit exposure field based on the detection result of the position detection system. A shape modification unit modifies a shape of the bright-dark pattern to be exposed on the substrate based on the deformation state calculated by the deformation calculation unit.

Hereinafter, the “unit exposure field” refers to an exposure field defined as a field on the substrate, in which a bright-dark pattern is formed through a single exposure operation (e.g., a one-shot exposure operation or a scanning exposure operation).

A second aspect of the present invention provides an exposure method for exposing a bright-dark pattern onto unit exposure fields on a substrate via a projection optical system. The exposure method includes a position detection step of detecting a plurality of predetermined positions in the exposure field of the substrate with a position detection system which detects the plurality of predetermined positions that fall within a range substantially equal to one of the exposure fields, a deformation calculation step of calculating a state of deformation in the unit exposure field based on information related to the plurality of predetermined positions obtained in the position detection step, and a shape modification step of modifying a shape of the bright-dark pattern to be exposed on the substrate based on the deformation state obtained in the deformation calculation step.

A third aspect of the present invention provides a method for manufacturing an electronic device including a lithography process. In the lithography process, the exposure method of the second aspect is used.

In the exposure apparatus and method of the embodiment according to the present invention, a plurality of positions in a unit exposure field are detected with, for example, a position detection system (one or more position detection units) that detects a plurality of positions that fall within a range that is substantially equal to a unit exposure field defined on a substrate. Based on information on the plurality of positions, the state of deformation occurring in the unit exposure field is calculated. In other words, deformation of an existing pattern that is formed in the unit exposure field is measured based on the information on the plurality of positions in the unit exposure field.

In the embodiment according to the present invention, the accuracy for superimposing patterns on the substrate is improved by modifying the shape of a bright-dark pattern exposed on the substrate in correspondence with deformation of an existing pattern formed in the unit exposure field. In this manner, the exposure apparatus and method of the embodiment according to the present invention enables rapid and accurate measurement of deformation occurring in the unit exposure field based on a plurality of position detection marks that are formed in a predetermined distribution. Thus, patterns are superimposed on the substrate with high accuracy, and electronic devices are manufactured with high accuracy.

### BRIEF DESCRIPTION OF THE SEVERAL VIEWS OF THE DRAWING

A general architecture that implements the various features of the invention will now be described with reference to the drawings. The drawings and the associated descriptions are provided to illustrate embodiments of the invention and not to limit the scope of the invention.

FIG. 1 is a schematic diagram showing an exposure apparatus according to an embodiment of the present invention;

FIG. 2 is a schematic diagram showing the interior of a position detection system shown in FIG. 1;

FIG. 3 is a schematic diagram showing the interior of each position detection unit in the position detection system shown in FIG. 1;

FIG. 4 is a schematic diagram showing the structure of a two-time imaging catadioptric projection optical system as one example of a projection optical system shown in FIG. 1;

FIG. 5 is a schematic diagram showing the interior of an optical surface shape modification unit shown in FIG. 1;

FIG. 6 is a flowchart illustrating an exposure sequence of the exposure method according to an embodiment of the present invention;

FIG. 7 is a schematic diagram showing a plurality of LSI circuit patterns and a plurality of position detection marks that are formed in a unit exposure field of a wafer;

FIG. 8 is a schematic diagram showing a position detection system according to a modification of the present invention;

FIG. 9 is a schematic diagram showing the structure of a position detection system according to another modification of the present invention;

FIG. 10 is a flowchart illustrating a method for manufacturing a semiconductor device; and

FIG. 11 is a flowchart illustrating a method for manufacturing a liquid crystal display device.

### DETAILED DESCRIPTION OF THE INVENTION

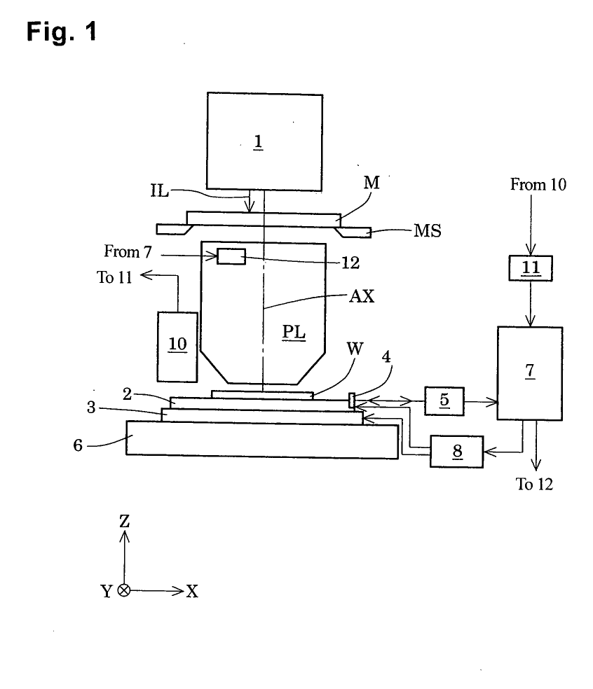

An embodiment of the present invention will now be described with reference to the drawings. FIG. 1 is a schematic diagram showing the structure of an exposure apparatus according to the embodiment of the present invention. In FIG. 1, X-axis and Y-axis are orthogonal to each other within a plane parallel to a surface (exposure surface) of a wafer W, whereas the Z-axis extends in a direction normal to the surface of the wafer W. More specifically, the XY plane extends horizontally and the (+)Z-axis extends upward in the vertical direction.

The exposure apparatus of the present embodiment shown in FIG. 1 includes an exposure light source, such as an ArF excimer laser, and an illumination unit 1, which includes an optical integrator (homogenizer), a field stop, and a condenser lens. The illumination unit 1 illuminates a mask (reticle) M, on which a pattern that is to be transferred is formed, with exposure light IL, which is emitted from the light source. The illumination unit 1 illuminates, for example, the entire rectangular pattern field of the mask M or an elongated slit region (e.g., a rectangular region) extending in the entire pattern field along the X-direction.

Light from the pattern of the mask M is made incident on a projection optical system PL, which has a predetermined reduction magnification. The projection optical system PL forms a pattern image (bright-dark pattern) of the mask M in a unit exposure field defined on the wafer (photosensitive substrate) W, which is coated with photoresist. More specifically, the projection optical system PL forms in the unit exposure field of the wafer W a mask pattern image in a rectangular region that is similar to the entire pattern field of the mask M or in an elongated rectangular region (stationary exposure field) extending in the X-direction, which optically corresponds to an illumination field (a field of view) on the mask M.

A mask stage MS supports the mask M in a manner that the mask M is parallel to the XY plane. The mask stage MS incorporates a mechanism for slightly moving the mask M in the X-direction, Y-direction, and a rotation direction about Z-axis. The mask stage MS includes a movable mirror (not shown). The X-position, Y-position, and rotation position of the mask stage MS (and the mask M) are measured in real time by a mask laser interferometer (not shown) that uses the movable mirror.

A wafer holder (not shown) supports the wafer W on a Z-stage 2 in a manner that the wafer W is parallel to the XY plane. The Z-stage 2 is fixed to an XY-stage 3. The XY-stage 3 moves along the XY plane, which is substantially parallel to an image plane of the projection optical system PL. The Z-stage 2 adjusts the focal position (Z-direction position) and the tilt angle of the wafer W (the tilt of the surface of the wafer W with respect to the XY plane). The Z-stage 2 includes a movable mirror 4. The X-position, Y-position, and rotation position about the Z-axis are measured in real time by a wafer laser interferometer 5 that uses the movable mirror 4. The XY-stage 3 is mounted on a base 6. The XY-stage 3 adjusts the X-position, Y-position, and rotation position of the wafer W.

An output of the mask laser interferometer and an output of the wafer laser interferometer 5 are provided to a main control system 7. The main control system 7 controls the X-position, Y-position, and rotation position of the mask M based on the values measured by the mask laser interferometer. More specifically, the main control system 7 transmits a control signal to the mechanism incorporated in the mask stage MS. The mechanism adjusts the X-position, Y-position, and rotation position of the mask M by finely moving the mask stage MS based on the control signal.

The main control system 7 controls the focal position and the tilt angle of the wafer W so that the surface of the wafer W is positioned to coincide with the image plane of the projection optical system PL through autofocusing and automatic leveling. More specifically, the main control system 7 transmits a control signal to a wafer stage drive system 8. The wafer stage drive system 8 drives the Z-stage 2 based on the control signal to adjust the focal position and the tilt angle of the wafer W.

The main control system 7 further controls the X-position, Y-position, and rotation position of the wafer W based on the values measured by the wafer laser interferometer 5. More specifically, the main control system 7 transmits a control signal to the wafer stage drive system 8. The wafer stage drive system 8 adjusts the X-position, Y-position, and rotation position of the wafer W by driving the XY stage 3 based on the control signal.

When a step-and-repeat system is performed, the pattern image of the mask M is one-shot exposed onto one of a plurality of unit exposure fields, which are arranged in a matrix on the wafer W. Afterwards, the main control system 7 transmits a control signal to the wafer stage drive system 8 and step-moves the XY-stage 3 along the XY plane using the wafer stage drive system 8 to align another unit exposure field of the wafer W with the projection optical system PL. In this manner, the one-shot exposure of the pattern image of the mask M onto a unit exposure field of the wafer W is repeated.

In the step-and-scan system, the main control system 7 transmits a control signal to the mechanism incorporated in the mask stage MS and a control signal to the wafer stage drive system 8. This scans and exposes a pattern image of the mask M onto a single unit exposure field on the wafer W while the mask stage MS and the XY stage 3 are being moved at a velocity ratio determined in accordance with the projection magnification of the projection optical system PL. Afterwards, the main control system 7 transmits a control signal to the wafer stage drive system 8 and step-moves the XY-stage 3 along the XY plane using the wafer stage drive system 8 to align another unit exposure field of the wafer W with the projection optical system PL. The scanning exposure operation of the pattern image of the mask M onto unit exposure fields of the wafer W is repeated in this manner.

More specifically, with the step-and-scan system, the mask stage MS and the XY-stage 3, and consequently the mask M and the wafer W, are moved (scanned) in synchronization with each other in the Y-direction that is the short side direction of the rectangular (normally slit-shaped) stationary exposure field while the positions of the mask M and the wafer W are controlled by the wafer stage drive system 8, the wafer laser interferometer 5, and the like. As a result, the mask pattern is scanned and exposed onto a region on the wafer W that has a width equal to the long side of the stationary exposure field and a length corresponding to a scanning amount (movement amount) of the wafer W.

To measure deformation occurring in each unit exposure field of the wafer W with high accuracy and improve the accuracy for superimposing patterns formed on the wafer W, the exposure apparatus of the present embodiment includes a position detection system 10, a deformation calculation unit 11, and an optical surface shape modification unit 12. The position detection system 10 detects a plurality of positions in each unit exposure field of the wafer W without via the projection optical system PL. The deformation calculation unit 11 calculates the state of deformation occurring in each unit exposure field of the wafer W based on the detection result of the position detection system 10. To correct the shape of a pattern image (bright-dark pattern) exposed onto the wafer W, the optical surface shape modification unit 12 modifies the shape of at least one optical surface of the projection optical system PL based on the calculation result of the deformation calculation unit 11.

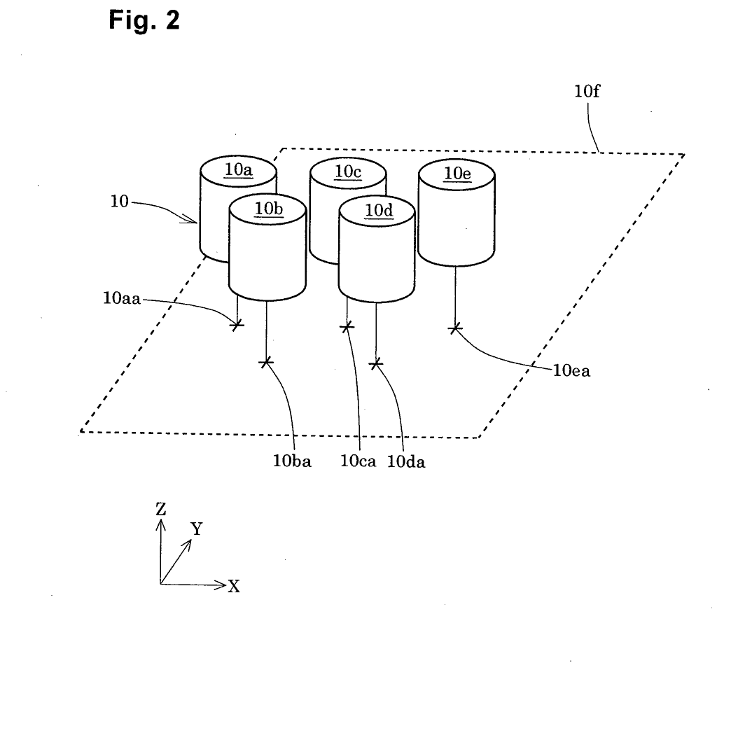

As shown in FIG. 2, the position detection system 10 includes a plurality of position detection units that are arranged two-dimensionally along the XY plane in a parallel arrangement manner. To simplify the drawing, FIG. 2 shows only five position detection units (position detection mechanisms) 10a, 10b, 10c, 10d, and 10e among the plurality of position detection units that form the position detection system 10. The position detection mechanisms 10a, 10b, 10c, 10d, and 10e are in a zigzag arrangement or in a parallel arrangement. The zigzag arrangement refers to an arrangement in which position detection mechanisms are alternately arranged toward the +Y direction and a −Y direction from a straight line extending in the X-direction. FIG. 2 shows two adjacent lines, namely, a first line including the position detection mechanisms 10a, 10c, and 10e and a second line including the position detection mechanisms 10b and 10d. The position detection mechanisms 10a, 10c, and 10e are offset in the +Y direction and arranged at predetermined intervals in the first line. The position detection mechanisms 10b and 10d are offset in the −Y direction and arranged at predetermined intervals in the second line. Reference detection positions 10aa to 10ea of the five position detection units 10a to 10e fall within a rectangular range 10f, which is substantially equal to one unit exposure field of the wafer W. In FIG. 2, the reference detection position of each of the position detection units 10a to 10e, which is indicated by a crossed mark, is the center of the detection region of each position detection unit. In the embodiment, the reference detection positions of the position detection mechanism forming the position detection system 10 all fall within the range 10f.

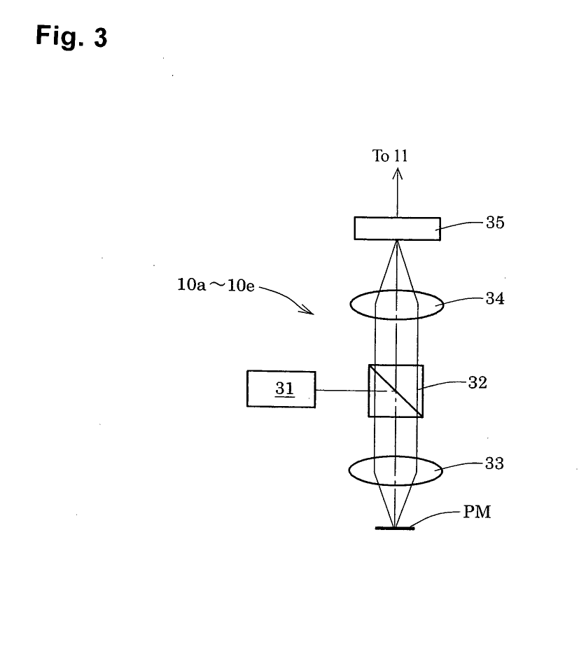

The position detection units 10a to 10e may be, for example, imaging-device-based position detection mechanisms. The position detection units 10a to 10e each have the same basic structure. In each of the imaging-device-based position detection units 10a to 10e, as shown in FIG. 3, illumination light emitted from an illumination unit 31 is reflected by a half prism 32, passes through a first objective lens 33, and illuminates a position detection mark PM formed in the unit exposure field of the wafer W. The illumination unit 31 may be arranged so that one is provided for each position detection units or so that the position detection units commonly use the same one.

Reflection light (including diffraction light) of the illumination light from the position detection mark PM passes through the first objective lens 33, the half prism 32, and a second objective lens 34 to form an image of the position detection mark PM on an imaging plane of an imaging device 35, which may be a CCD camera. More specifically, the CCD camera 35 functions as a photoelectric detector (light detection unit) for photoelectrically detecting the image of the position detection mark PM, which is formed through an imaging optical system that includes the first objective lens 33 and the second objective lens 34.

The CCD camera 35 processes a photoelectric detection signal (processes the waveform) based on the detected image of the position detection marks PM with an internal signal processing unit (not shown). Through such processing, the CCD camera 35 obtains, for example, the X and Y coordinates representing the central position of each position detection mark PM as position information of the position detection mark PM. The CCD camera 35 outputs the position information of the position detection marks PM. The position information of the position detection marks PM is provided to the deformation calculation unit 11 as the output of the position detection units 10a to 10e (or the output of the position detection system 10).

The deformation calculation unit 11 calculates the state of deformation occurring in the unit exposure field based the detection result of the position detection system 10, that is, the position information (a plurality of position detection values) of the plurality of position detection marks PM formed in the unit exposure field of the wafer W. More specifically, the deformation calculation unit 11 detects a positional deviation amount of each position detection mark PM formed in the unit exposure field of the wafer W from the corresponding reference position. Based on the information on the positional deviation amount of each position detection mark PM, the deformation calculation unit 11 approximates deformation occurring in the unit exposure field with, for example, a nonlinear function defined using X and Y coordinates.

It is assumed here that high-level deformation that occurs in the unit exposure field is expressed by a higher-order function using X and Y coordinates. The coordinates indicating the designed position of the position detection mark PM (hereafter referred to as “design value”) is represented by (Dxn, Dyn). The coordinates indicating the actually detected position of the position detection mark PM (hereafter referred to as “measurement value”) is represented by (Fxn, Fyn). Variable factors a to f (primary variable elements) and variable factors g to j (higher-order variable elements) indicate causes of the positional deviation between the design value and the measurement value. In this case, the relationship between the actual measurement value and the design value is represented by formula (1), which is shown below. In the formula (1), n is an integer indicating the number given to each position detection mark PM formed in the unit exposure field.

$$[ \begin{matrix}Fxn \\ Fyn\end{matrix} ] = [ \begin{matrix}a & b \\ c & d\end{matrix} ] [ \begin{matrix}Dxn \\ Dyn\end{matrix} ] + [ \begin{matrix}e \\ f\end{matrix} ] + [ \begin{matrix}g {Dxn}^{2} \\ h {Dyn}^{2}\end{matrix} ] + [ \begin{matrix}i {Dxn}^{3} \\ j {Dyn}^{3}\end{matrix} ] \qquad ( 1 )$$

However, a positional deviation amount, or a residual error term (Exn, Eyn), exists between the design value (Dxn, Dyn) and the actual measurement value (Fxn, Fyn). Thus, the relationship between the actual measurement value and the design value that takes into consideration the residual error term is represented by formula (2).

$$[ \begin{matrix}Fxn \\ Fyn\end{matrix} ] = [ \begin{matrix}a & b \\ c & d\end{matrix} ] [ \begin{matrix}Dxn \\ Dyn\end{matrix} ] + [ \begin{matrix}e \\ f\end{matrix} ] + [ \begin{matrix}g {Dxn}^{2} \\ h {Dyn}^{2}\end{matrix} ] + [ \begin{matrix}i {Dxn}^{3} \\ j {Dyn}^{3}\end{matrix} ] + [ \begin{matrix}Exn \\ Eyn\end{matrix} ] \qquad ( 1 )$$

The x-element in formula (2) can be expressed as formula (3).

Exn=Fxn−(aDxn+bDyn+e+gDxn²+iDxn³) (3)

In the same manner, the y-element in formula (2) can be expressed as formula (4).

Eyn=Fyn−(cDxn+dDyn+f+hDyn²+jDyn³) (4)

Each variable element is determined to minimize the square sum of the residual error term with, for example, a least-squares method. In this manner, the deformation occurring in the unit exposure field can be approximated using the higher-order function.

The approximation with the higher-order function described above uses second-order and third-order elements as the higher-order elements. However, the approximation may also use fourth or higher-order elements. The deformation occurring in the unit exposure field may also be approximated with a function system represented in polar coordinates. In this case, wavefront aberration of the optical system can be expressed using series expansions such as the Zernike expansion.

The reference position of each position detection mark PM is either its designed position or its actual position measured immediately after the position detection mark PM is formed and before wafer processing. Approximating the deformation occurring in the unit exposure field of the wafer W with a function using the deformation calculation unit 11 is equivalent to approximating the deformation occurring in the existing circuit pattern formed in the unit exposure field of the wafer W with a function.

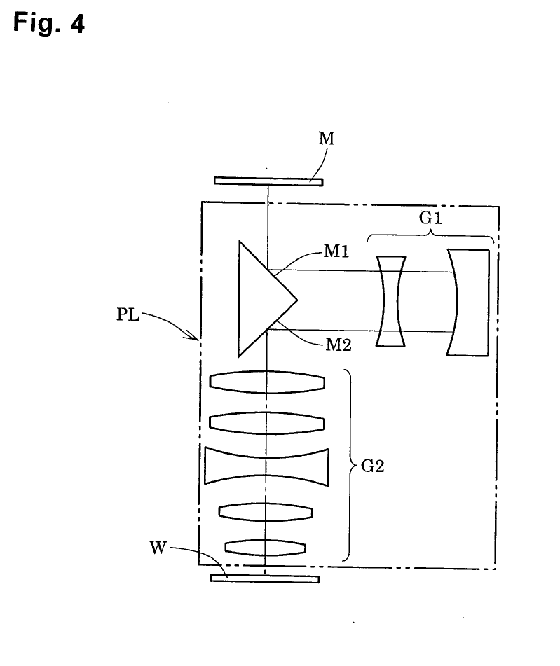

The optical surface shape modification unit 12 functions to modify the aberration of the projection optical system PL by modifying the shape of at least one optical surface of the projection optical system PL. Hereafter, a two-time imaging catadioptric projection optical system PL shown in FIG. 4 will be used as an example to describe the detailed structure of the optical surface shape modification unit 12. The projection optical system PL in FIG. 4 includes a catadioptric first imaging optical system G1 and a dioptric second imaging optical system G2. The first imaging optical system G1 forms an intermediate image of the pattern of the mask M. The second imaging optical system G2 forms a final reduced image of the mask pattern on the wafer W based on light from the intermediate image.

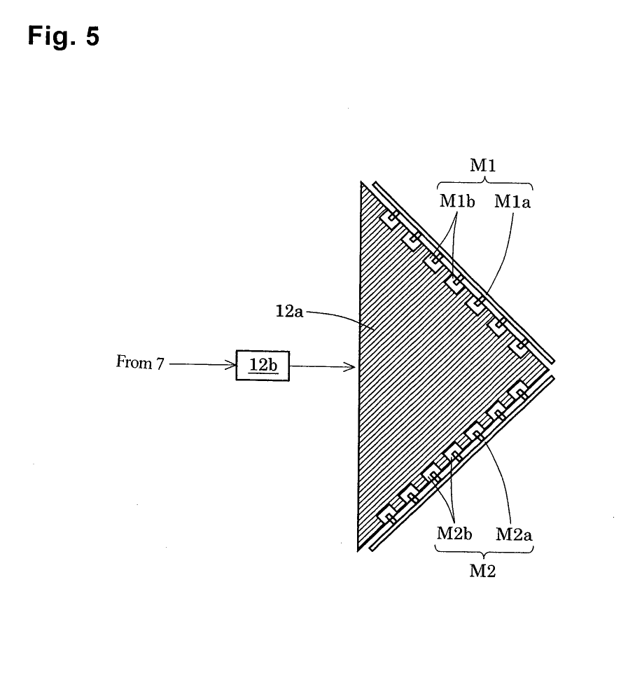

A plane mirror M1, which may be a deformable mirror, is arranged in an optical path extending from the mask M to the first imaging optical system G1. Further, a plane mirror M2, which is formed by a deformable mirror, is also arranged in an optical path extending from the first imaging optical system G1 to the second imaging optical system G2. A reflection surface of the plane mirror M1 is positioned near to the mask M. A reflection surface of the plane mirror M2 is arranged at an intermediate image formation position or positioned near the intermediate image formation position. As shown in FIG. 5, the plane mirror M1 includes, for example, a reflection member M1a having a reflection surface and a plurality of drive elements M1b arranged next to each other in a two-dimensional manner in correspondence with the reflection surface of the reflection member M1a. In the same manner, the plane mirror M2 includes a reflection member M2a having a reflection surface and a plurality of drive elements M2b arranged next to each other in a two-dimensional manner in correspondence with the reflection surface of the reflection member M2a.

In addition to the plane mirrors M1 and M2, the optical surface shape modification unit 12 includes a mirror substrate 12a, which is shared by the plane mirrors M1 and M2, and a drive unit 12b, which independently drives the plurality of drive elements M1b and M2b. The drive unit 12b independently drives the drive elements M1b and M2b based on a control signal provided from the main control system 7, which has received the output of the deformation calculation unit 11. The drive elements M1b and M2b are attached to the common mirror substrate 12a. The drive elements M1b and M2b modify the shapes of the reflection surfaces of the reflection members M1a and M2a to a desired shape through independent push-and-pull operations.

In this manner, the optical surface shape modification unit 12 deforms or modifies the shape of at least either one of the reflection surface of the plane mirror M1, which is arranged near an object plane of the projection optical system PL, and the reflection surface of the plane mirror M2, which is arranged at a position optically conjugate to the object plane of the projection optical system PL or near the conjugate position. This modifies the aberration state of the projection optical system PL and actively generates distortion of the projection optical system PL. As a result, the optical surface shape modification unit 12 modifies the shape of the mask pattern image (bright-dark pattern) exposed onto the unit exposure field of the wafer W.

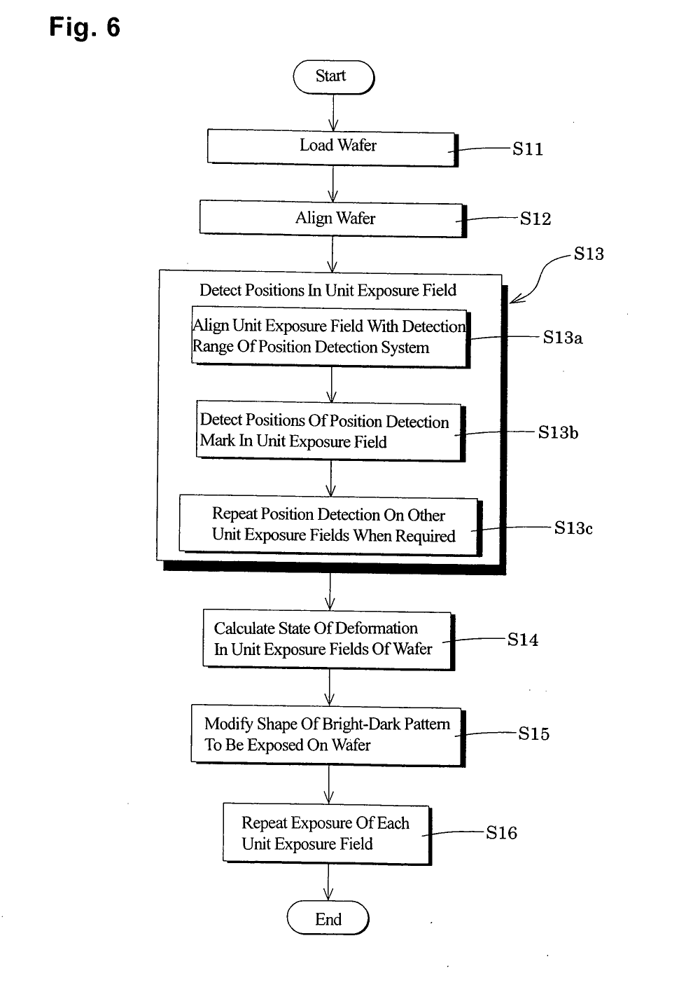

FIG. 6 is a flowchart schematically showing an exposure sequence of the exposure method according to an embodiment of the present invention. To facilitate understanding of the present invention, it will hereafter be assumed that the exposure method of the present embodiment is used for one-shot exposure of the pattern of the mask M onto each unit exposure field of the wafer W with the use of the exposure apparatus of FIG. 1. Referring to FIG. 6, in the exposure method of the present embodiment, a wafer W, which has one or more circuit patterns exposed thereon and which has been subjected to wafer processing, is loaded onto the Z-stage 2 (S11). Then, the wafer W is aligned with the projection optical system PL (and the mask M) (S12).

In the alignment process S12, the XY-stage 3 is driven as required based on information related with the outer shape of the wafer W or the like. This pre-aligns (roughly aligns) the wafer W with the projection optical system PL. In the alignment process S12, the positions of a plurality of wafer alignment marks formed on the wafer W are detected via, for example, the position detection system 10 shown in FIG. 1, and the XY-stage 3 is driven as required based on the position information. This finely aligns (precisely aligns) the wafer W with the projection optical system PL.

For fine alignment of the wafer W, one or more position detection marks selected from a plurality of position detection marks PM formed in the unit exposure field, which will be described later, may be used as a plurality of wafer alignment marks of which positions are detected. In the alignment process S12, the projection optical system PL optically aligns the mask M on which a transferred pattern is formed and the wafer W on which the circuit patterns have been formed, and consequently the pattern field on the mask M and the unit exposure field on the wafer W.

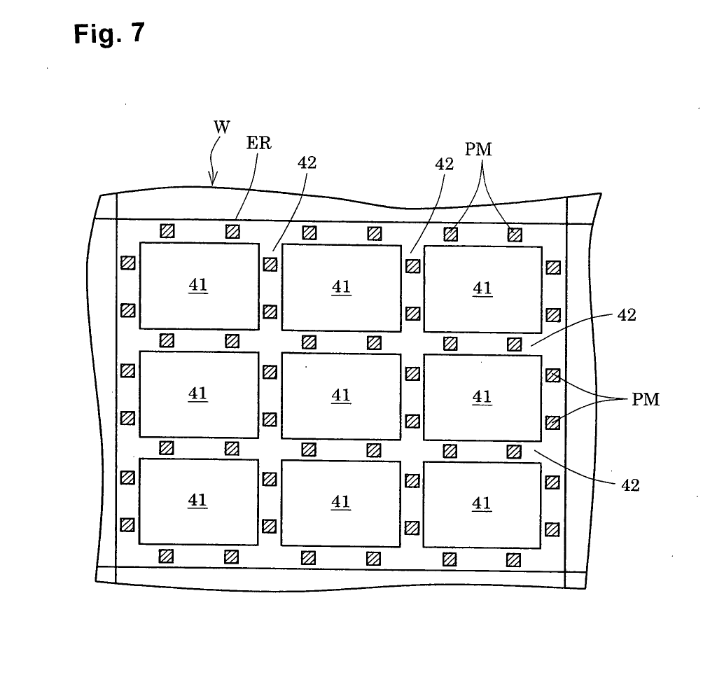

As shown in FIG. 7, a total of nine circuit patterns 41, each of which corresponds to a functional element such as an LSI circuit, are formed in three lines in the X-direction and three lines in the Y-direction in each unit exposure field of the wafer W, which has been loaded on the Z-stage 2. The “functional element” is a minimum unit that functions as a single independent electronic device, that is, a single chip. In a preceding or earlier lithography process, a plurality of position detection marks PM are formed in a street line 42 (or a “cutting margin” portion between the chips) of each unit exposure field ER. More specifically, a total of 24 position detection marks PM are formed in a peripheral portion of the unit exposure field ER shown in FIG. 7, or in an inner portion extending along the contour boundary of the unit exposure field ER. For example, a total of 24 position detection marks PM are formed between two adjacent LSI circuit patterns 41.

Although not shown in the drawings, the mask M, which is used to form a plurality of position detection marks PM, has circuit patterns corresponding to nine LSI circuit patterns 41 in the pattern field. The mask M also has a plurality of marks corresponding to the plurality of position detection marks PM in a marginal area (remaining portions in which circuit patterns are not formed) corresponding to the street line 42. Accordingly, in the structure in which position detection marks PM are formed in the street line 42 of each unit exposure field ER, the freedom of design for an LSI circuit is substantially unaffected. In FIG. 7, the width of the street line 42 and the size of each position detection mark PM are exaggerated with respect to the LSI circuit patterns 41 for the sake of brevity.

The exposure method of the present embodiment next detects the positions of the plurality of position detection marks PM in at least one unit exposure field ER of the wafer W (S13). In the position detection process S13, the XY-stage 3 is driven to align a specific unit exposure field ER of the wafer W with the detection range 10f of the position detection system 10 (S13a). The plurality of position detection units forming the position detection system 10 then detect the wafer-in-plane-direction positions of the plurality of position detection marks PM in the unit exposure field ER (S13b). In the detection process S13b, the positions of the numerous position detection marks PM formed in the unit exposure field ER may be detected at the same time (substantially simultaneously) by the position detection units, the quantity of which is the same as that of the position detection marks PM. Alternatively, the positions of the numerous position detection marks PM may be detected over a number of times.

Further, in the detection process S13b, the positions of selected ones of the numerous position detection marks PM formed in the unit exposure field ER may be detected at the same time by position detection units, the quantity of which is the same as that of the selected position detection marks PM. Alternatively, the positions of the selected position detection marks PM may be detected over a number of times. Further, another unit exposure field ER of the wafer W may be aligned with the detection range 10f of the position detection system 10 when necessary and the position detection operation of the positions of a plurality of position detection marks PM in the other unit exposure field ER may be repeated (S13c). The wafer W may be aligned with the projection optical system PL (and the mask M) in the position detection process S13 to eliminate the alignment process S12.

Next, in the exposure method of the present embodiment, the state of deformation occurring in the unit exposure field ER of the wafer W is calculated based on the position information obtained in the position detection process S13 (S14). In the deformation calculation process S14, the deformation calculation unit 11, which has received the detection result of the position detection system 10, calculates a position deviation amount of each of the plurality of position detection marks PM formed in the unit exposure field ER of the wafer W from the corresponding reference position and then approximates the deformation occurring in the unit exposure field ER with a function based on the information on the position deviation amount of each position detection mark PM. In the deformation calculation process S14, the deformation state may be calculated for every unit exposure field that has been subjected to the position detection process S13. In this manner, the positions of the plurality of position detection marks PM in the unit exposure field ER are detected for example at the same time via the plurality of position detection units in the position detection process S13. This enables deformation occurring in the unit exposure field ER, or deformation occurring in the LSI circuit patterns, to be measured (calculated) rapidly and accurately in the deformation calculation process S14.

The exposure method of the present embodiment next includes modifying the shape of a bright-dark pattern exposed onto the unit exposure field ER of the wafer W as necessary based on information on the deformation state obtained in the deformation calculation process S14 (S15). When the unit exposure field ER of the wafer W has been deformed during the wafer processing or the like, the existing circuit patterns formed in the unit exposure field ER have also been deformed and deviated from the desired design patterns. Thus, when the state of deformation occurring in the unit exposure field ER exceeds its allowable range, a new circuit pattern (bright-dark pattern) exposed on the existing circuit patterns in the unit exposure field ER will not be superimposed on the existing circuit patterns with accuracy.

In the exposure method of the present embodiment, the reflection surface of at least one of the plane mirrors M1 and M2 is deformed as required based on an instruction provided from the main control system 7 in the shape modification process S15. This actively generates, for example, a predetermined amount of distortion in the projection optical system PL. As a result, the shape of the bright-dark pattern exposed in the unit exposure field ER is modified to in correspondence with the deformation of the existing circuit patterns in the unit exposure field ER.

Finally, the exposure method of the present embodiment includes repeating the projection exposure for each unit exposure field ER of the wafer W (S16). As a general rule, the same circuit pattern is exposed in each unit exposure field ER. Thus, when deformation occurring in each unit exposure field ER does not substantially depend on the position of each unit exposure field ER on the wafer W but mainly depends on the characteristics of the circuit pattern exposed in each unit exposure field ER, the state of deformation occurring in one representative unit exposure field obtained in the deformation calculation process S14 is used to set a desired aberration for the projection optical system PL. In this state, the projection exposure is repeated for each unit exposure field ER. Alternatively, in this case, the projection exposure process S16 may repeat the projection exposure for each unit exposure field ER while the shape modification process S15 maintaining a constant desired aberration of the projection optical system PL based on the average of values representing the state of deformation occurring in the plurality of unit exposure fields obtained in the deformation calculation process S14.

When deformation occurs in each unit exposure field ER depends on the position of each unit exposure field ER on the wafer W (e.g., depends on whether the unit exposure field ER is at a middle position, a peripheral position, or the like on the wafer W), the aberration of the projection optical system PL may be modified as required based on the state of deformation occurring in each of the plurality of unit exposure fields that are located at different positions on the wafer W in the projection exposure process S16. In this state, the projection exposure may be repeated for each unit exposure field ER. Alternatively, in this case, the projection exposure process S16 may repeat the projection exposure for each unit exposure field ER while adjusting the aberration of the projection optical system PL for every unit exposure field based on the state of deformation occurring in each unit exposure field of the wafer W.

As described above, in the exposure apparatus and method of the present embodiment, the position detection system (plurality of position detection units) 10 for detecting a plurality of positions that fall within a range substantially equal to each unit exposure field ER of the wafer W is used to detect the wafer-in-plane direction positions of a plurality of position detection marks PM formed in the unit exposure field ER. Based on position information (position detection values) on the plurality of position detection marks PM, the state of deformation occurring in each unit exposure field ER is calculated, and consequently, deformation occurring in the existing circuit pattern formed in the unit exposure field ER is measured.

Accordingly, in the present embodiment, the shape of the bright-dark pattern exposed in the unit exposure field is modified in correspondence with the deformation of the existing circuit patterns in the unit exposure field ER. This improves the superimposing accuracy of newly exposed patterns and the existing circuit patterns on the wafer W. As a result, the exposure apparatus and method of the present embodiment enables deformation occurring in the unit exposure field ER to be detected rapidly and accurately and enables patterns to be superimposed on the wafer W with high accuracy.

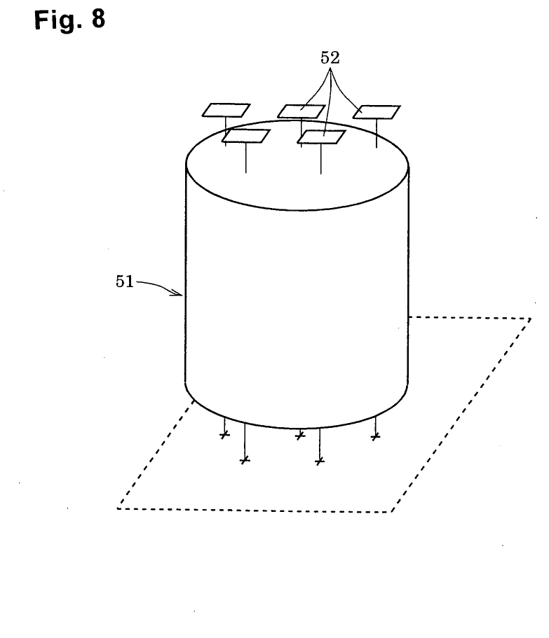

In the above embodiment, the plurality of detection optical systems (32 to 34) that are parallel arranged next to each other in a two-dimensional manner and the photoelectric detectors 35, the quantity of which is the same as the detection optical systems, form the plurality of position detection units. However, the present invention is not limited to such a structure. The number, arrangement, and structure of the position detection units may be variously. Specifically, as shown in FIG. 8 for example, a single common detection optical system 51, which is commonly used to detect the positions of a plurality of position detection marks, and a plurality of imaging devices (photodetectors) 52, which are arranged in and above a detection range of the common detection optical system 51, may form a plurality of position detection units. The plurality of independent imaging devices 52 are used in the example shown in 8. However, a plurality of portions of an imaging plane of a single imaging device may be used as a plurality of photodetectors instead of the plurality of independent imaging devices 52. The structure in the example shown in FIG. 8 may be changed to include a plurality of common detection optical systems 51, or to additionally include one or more position detection units having the structure shown in FIG. 2.

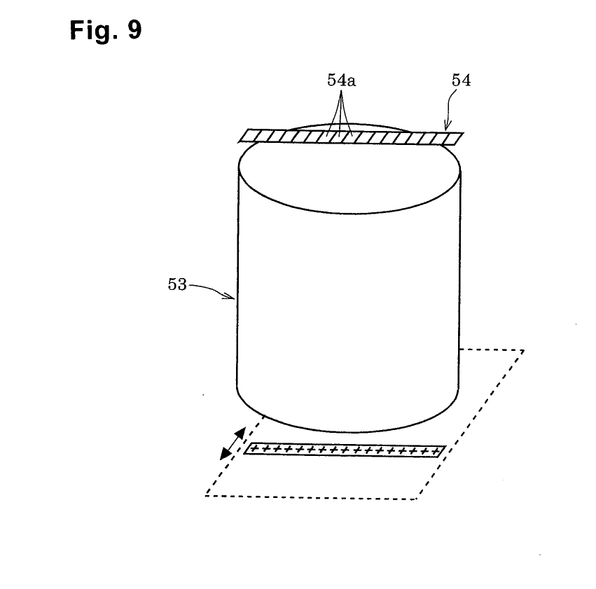

Alternatively, as shown in FIG. 9, a single common detection optical system 53, which is commonly used to detect the positions of a plurality of position detection marks, and a line sensor (photodetector) 54, which is formed by, for example, a plurality of imaging devices 54a arranged in one direction to detect light with the common detection optical system 53, may form a plurality of position detection units. In this case, the positions of the plurality of position detection marks are scan-detected while moving the wafer W with the XY-stage 3 relative to the common detection optical system 53 in a direction orthogonal to the direction in which the plurality of imaging devices 54a are arranged. The structure in the example shown in FIG. 9 may include a plurality of common detection optical systems 53 or a plurality of line sensors 54 parallel arranged next to each other.

Although the imaging-device-based position detection mechanisms are used in the above embodiment, the present invention is not limited to such a structure. The detection method of the position detection mechanisms may be modified in various manners. For example, a laser-scanning position detection mechanism may be used to detect the position of a position detection mark that is formed by, for example, a stepped mark by scanning the position detection mark with a slit-shaped laser beam spot and detecting light scattered from the position detection mark via a photodetector. Alternatively, a grating-alignment position detection mechanism may be used to measure the position of a position detection mark that is formed by, for example, a grating mark by diagonally illuminating the position detection mark with light beams in two directions and detecting light reflected from the position detection mark via a photodetector.

Although the optical surface shape modification unit 12 modifies the shape of the reflection surfaces of the plane mirrors M1 and M2 formed by deformable mirrors when required, the present invention is not limited to such a structure. For example, the optical surface shape modification unit 12 may modify the shape of the optical surface of the projection optical system when required by locally deforming a plane-parallel glass plate. In the above embodiment, the optical surface shape modification unit 12 modifies the shape of the reflection surface of the plane mirror M1 or M2 when required to modify the aberration of the projection optical system PL, generate a predetermined amount of deformation of the projection optical system PL, and modify the shape of a bright-dark pattern exposed onto the wafer W. However, the present invention is not limited to this structure. The optical surface shape modification unit 12 may modify the shape of at least one optical surface arranged at a position near to the object plane of the projection optical system, at a position optically conjugate to the object plane or near to the conjugate position, or a position near the image plane of the projection optical system. In this case, the optical surface shape modification unit 12 can generate a predetermined amount of deformation without substantially any aberration.

Normally, the aberration of the projection optical system can be modified and the shape of a bright-dark pattern exposed onto the substrate can be modified by modifying the shape of at least one optical surface of the projection optical system. Further, the shape of the bright-dark pattern exposed on the substrate may normally also be modified by modifying the aberration of the projection optical system. The shape of the bright-dark pattern exposed on the substrate can also be modified by modifying the shape of the pattern surface of the mask in addition to or instead of modifying the aberration of the projection optical system.

Although the embodiment according to the present invention is applied to a one-shot exposure method for performing one-shot exposure of the pattern of the mask M in each unit exposure field of the wafer W in the above embodiment, the present invention is not limited to the one-shot exposure method. The embodiment according to the present invention may be applied to a scanning exposure method for performing scanning exposure of the pattern of the mask M in each unit exposure field of the wafer W. In this case, the shape of a bright-dark pattern exposed on the substrate must be modified in accordance with relative movement of the substrate during scanning exposure.

Although the embodiment according to the present invention is applied to the exposure apparatus and method using the mask M on which a pattern to be transferred is formed, the application of the present invention is not limited to the apparatus and method using the mask M. The present invention may also be applied to maskless exposure. In this case, a pattern generation device that forms a predetermined pattern based on predetermined electronic data may be used instead of the mask. A reflective spatial light modulator that is driven based on predetermined electronic data (e.g., a digital micromirror device) may be used, for example, as the pattern generation device. An exposure apparatus that uses such a reflective spatial light modulator is described, for example, in U.S. Pat. No. 5,523,193. The exposure apparatus using the reflective spatial light modulator modifies the shape of a bright-dark pattern exposed on a substrate by modifying predetermined electronic data, which is used to form for example a predetermined pattern, in accordance with the state of deformation in the unit exposure field obtained in the deformation calculation process S14. A transmissive spatial light modulator or a light-emitting image display element may be used instead of the reflective spatial light modulator.

The exposure apparatus of the above embodiment is fabricated by assembling various subsystems, which include the elements given in the scope of claim of the present application, so as to maintain predetermined mechanical precision, electric precision, and optical precision. To maintain the mechanical, electric, and optical precisions, the optical systems are adjusted to achieve the optical precision, the mechanical systems are adjusted to achieve the mechanical precision, and the electric systems are adjusted to achieve the electric precision. The process of assembling the subsystems into the exposure apparatus includes mechanically connecting the subsystems to one another, wiring the electric circuits, and piping the pressure circuits. Processes of assembling the subsystems are performed before the process for assembling the subsystems to the exposure apparatus. After the process of assembling the subsystems to the exposure apparatus is completed, the apparatus is subjected to overall adjustment to maintain precisions. The exposure apparatus is preferably fabricated in a clean room under controlled conditions including temperature and cleanness.

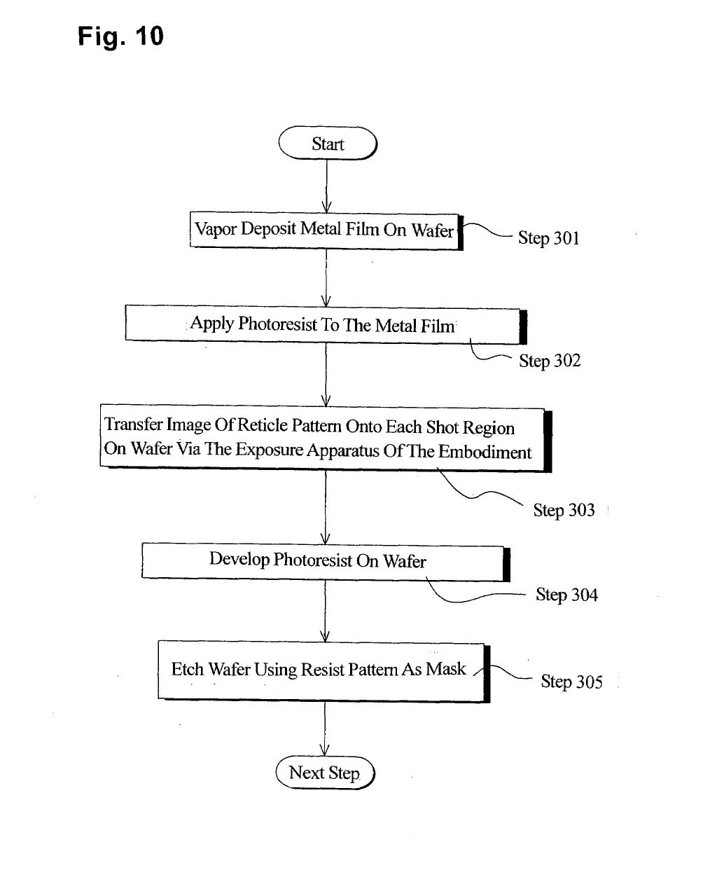

The exposure apparatus of the above embodiment, with which a pattern is exposed onto the photosensitive substrate via the projection optical system (exposure process), may be used to manufacture electronic devices (including semiconductor devices, imaging devices, liquid crystal display devices, and thin-film magnetic heads). One example method for manufacturing an electronic device or specifically a semiconductor device through formation of a predetermined circuit pattern on a photosensitive substrate, such as a wafer, with the exposure apparatus of the present embodiment will now be described with reference to a flowchart shown in FIG. 10.

In step S301 shown in FIG. 10, a metal film is first formed on wafers of a first lot through vapor deposition. In step S302, photoresist is applied to the metal film formed on each wafer of the first lot. In step S303, an image of a pattern formed on a mask is exposed and transferred sequentially onto shot-regions of each wafer of the first lot using the projection optical system with the exposure apparatus of the present embodiment. In step S304, the photoresist formed on each wafer of the first lot is developed. In step S305, each wafer of the first lot is etched using the resist pattern formed on the wafer as a mask. This forms a circuit pattern corresponding to the mask pattern in the shot-regions of each wafer.

Afterwards, circuit patterns for upper layers are formed to complete the semiconductor device or the like. With the semiconductor device manufacturing method described above, a semiconductor device with a fine circuit pattern is manufactured with a high throughput. In steps S301 to S305, metal is deposited on the wafer through vapor deposition, resist is applied to the metal film, and then the processes in which the resist is exposed, developed, and etched are performed. Prior to these processes, a silicon oxide film may first be formed on the wafer, the resist may be applied to the silicon oxide film, and the processes in which the resist is exposed, developed, and etched may then be performed.

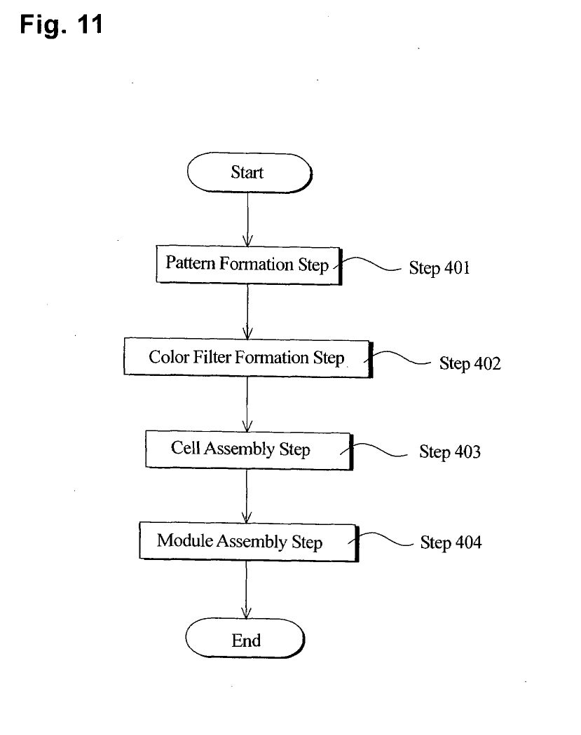

With the exposure apparatus of the present embodiment, an electronic device such as a liquid crystal display device may be manufactured through formation of a predetermined pattern (a circuit pattern or an electrode pattern) on a plate (glass substrate). One example of a method for manufacturing a liquid crystal display device will now be described with reference to a flowchart shown in FIG. 11. In FIG. 11, a pattern formation process is performed in step S401. In step S401, a mask pattern is transferred and exposed onto a photosensitive substrate (e.g., a glass substrate coated with resist) with the exposure apparatus of the present embodiment. In other words, a photolithography process is performed. Through the photolithography process, a predetermined pattern including many electrodes is formed on the photosensitive substrate. Afterwards, a predetermined pattern is formed on the substrate through processes including a developing process, an etching process, and a resist removing process. Then, a color filter formation process is performed in step S402.

In the color filter formation process S402, a color filter is formed by, for example, arranging many sets of R (red), G (green), and B (blue) dots in a matrix, or arranging a plurality of sets of filters formed by R, G, and B stripes in horizontal scanning line directions. After the color filter formation process S402, a cell assembly process is performed in step S403. In step S403, the substrate having a predetermined pattern obtained through the pattern formation process S401 and the color filter or the like obtained through the color filter formation process S402 are assembled together to form the liquid crystal panel (liquid crystal cell).

In the cell assembly process S403, for example, liquid crystal is injected between the substrate having the predetermined pattern obtained through the pattern formation process S401 and the color filter obtained through the color filter formation process S402 to form the liquid crystal panel (liquid crystal cell). In a module assembly process performed subsequently in step S404, an electric circuit for enabling the assembled liquid crystal panel (liquid crystal cell) to perform a display operation and other components including a backlight are mounted. This completes the liquid crystal display device. With the liquid crystal display device manufacturing method described above, a liquid crystal display device having a fine circuit pattern is manufactured with a high throughput.

The invention is not limited to the fore going embodiments but various changes and modifications of its components may be made without departing from the scope of the present invention. Also, the components disclosed in the embodiments may be assembled in any combination for embodying the present invention. For example, some of the components may be omitted from all components disclosed in the embodiments. Further, components in different embodiments may be appropriately combined.

What is claimed is:

1. An exposure apparatus that exposes a bright-dark pattern on a substrate via a projection optical system, the exposure apparatus comprising:
a position detection system which detects a plurality of predetermined positions in a unit exposure field of the substrate, wherein a plurality of reference detection positions fall within a range substantially equal to the unit exposure field;
a deformation calculation unit which calculates a state of deformation in the unit exposure field based on the detection result of the position detection system; and
a shape modification unit which modifies a shape of the bright-dark pattern to be exposed on the substrate based on the deformation state calculated by the deformation calculation unit.

2. The exposure apparatus according to claim 1, wherein the position detection system include at least four position detection units, each having a reference detection position that falls within a range substantially equal to the unit exposure field.

3. The exposure apparatus according to claim 1, wherein the position detection system includes a plurality of detection optical systems parallel arranged next to one another, wherein each detection optical system has a reference detection position that falls within a range substantially equal to the unit exposure field.

4. The exposure apparatus according to claim 3, wherein the position detection system includes a plurality of light detection units which detects light passing through the plurality of detection optical systems.

5. The exposure apparatus according to claim 1, wherein the position detection system includes at least one detection optical system and a plurality of light detection units arranged in a detection range of the at least one detection optical system.

6. The exposure apparatus according to claim 1, wherein the position detection system includes a common detection optical system and a plurality of light detection units parallel arranged next to one another to detect light passing through the common detection optical system.

7. The exposure apparatus according to claim 6, wherein the position detection system includes a relative moving device that moves the substrate relative to the common detection optical system.

8. The exposure apparatus according to claim 7, wherein the relative moving device includes a substrate stage which holds the substrate.

9. The exposure apparatus according to claim 1, wherein the position detection system detects each of the predetermined positions without the use of the projection optical system.

10. The exposure apparatus according to claim 1, wherein the shape modification unit includes an optical surface shape modification unit which modifies the shape of at least one optical surface in the projection optical system.

11. The exposure apparatus according to claim 10, wherein the at least one optical surface is arranged at a position near an object plane of the projection optical system, a position optically conjugate to the object plane or near the conjugate position, or a position near an image plane of the projection optical system.

12. The exposure apparatus according to claim 1, wherein the exposure apparatus is configured to form an image of a pattern formed on a mask arranged on the object plane of the projection optical system as the bright-dark pattern on the substrate.

13. The exposure apparatus according to claim 1, wherein the projection optical system has a reduction magnification.

14. The exposure apparatus according to claim 1, wherein the shape modification unit includes a mask surface shape modification unit which modifies the shape of a pattern surface of a mask arranged on an object plane of the projection optical system.

15. The exposure apparatus according to claim 1, wherein the deformation state calculated by the deformation calculation unit includes a high-level deformation state in the substrate or the unit exposure field.

16. The exposure apparatus according to claim 1, wherein:
the exposure apparatus is configured to scan and expose the bright-dark pattern onto the substrate while moving the substrate relative to the projection optical system in a predetermined direction; and
the shape modification unit is configured to modify the shape of the bright-dark pattern in accordance with relative movement of the substrate during the scanning exposure.

17. An exposure method for exposing a bright-dark pattern onto unit exposure fields on a substrate via a projection optical system, the exposure method comprising:
a position detection step of detecting a plurality of predetermined positions in a unit exposure field of the substrate with a position detection system which detects the plurality of predetermined positions that fall within a range substantially equal to one of the unit exposure fields;
a deformation calculation step of calculating a state of deformation in the unit exposure field based on information related to the plurality of predetermined positions obtained in the position detection step; and
a shape modification step of modifying a shape of the bright-dark pattern to be exposed on the substrate based on the deformation state obtained in the deformation calculation step.

18. The exposure method according to claim 17, wherein the position detection step includes detecting at least four predetermined positions.

19. The exposure method according to claim 17, wherein the position detection step includes detecting the plurality of predetermined positions with a plurality of detection optical systems parallel arranged next to one another in the position detection system.

20. The exposure method according to claim 19, wherein the position detection step includes detecting light passing through the plurality of detection optical systems with a plurality of position detection units.

21. The exposure method according to claim 17, wherein the position detection step includes detecting light passing through at least one detection optical system with a plurality of light detection units included in the position detection system and arranged in a detection range of the at least one detection optical system.

22. The exposure method according to claim 17, wherein the position detection step includes detecting light passing through a common detection optical system included in the position detection system with a plurality of light detection units parallel arranged next to one another.

23. The exposure method according to claim 22, wherein the position detection step includes detecting the plurality of predetermined positions while moving the substrate relative to the common detection optical system.

24. The exposure method according to claim 17, wherein the position detection step includes detecting the plurality of predetermined positions without the use of the projection optical system.

25. The exposure method according to claim 17, wherein the shape modification step includes an optical surface shape modification step of modifying the shape of at least one optical surface in the projection optical system.

26. The exposure method according to claim 25, wherein the shape modification step includes modifying the shape of an optical surface arranged at a position near an object plane of the projection optical system, a position optically conjugate to the object plane or near the conjugate position, or a position near an image plane of the projection optical system.

27. The exposure method according to claim 17, wherein the bright-dark pattern formed on the substrate is an image of a pattern formed on a mask.

28. The exposure method according to claim 17, wherein the bright-dark pattern is exposed on the substrate with the projection optical system that has a reduction magnification.

29. The exposure method according to claim 17, wherein the shape modification step includes a mask surface shape modification step of modifying the shape of a pattern surface of a mask arranged on an object plane of the projection optical system.

30. The exposure method according to claim 17, wherein the deformation state obtained in the deformation calculation step includes a high-level deformation state in the substrate or the unit exposure field.

31. The exposure method according to claim 17, further comprising:
a scanning exposure step of scanning and exposing the bright-dark pattern onto the substrate while moving the substrate relative to the projection optical system in a predetermined direction;
wherein the shape modification step includes modifying the shape of the bright-dark pattern in accordance with relative movement of the substrate during the scanning exposure.

32. A method for manufacturing an electronic device, the method comprising:
a lithography step using the exposure method according to claim 17.
